(19) United States
(12) Patent Application Publication
(10) Pub. No.: US 2026/0247923 A1
(43) Pub. Date: Aug. 20, 2026

(54) LOCALIZED WAFER PRE-COOLING FOR HYPERSPECTRAL IMAGING SYSTEM AND METHOD FOR THREE-DIMENSION (3D) DEFECT ANALYSIS IN WAFERS

(71) Applicant: Tokyo Electron Limited, Tokyo (JP)

(72) Inventors: Anton DEVILLIERS, Albany, NY (US); Daniel FULFORD, Albany, NY (US); Mark I. GARDNER, Albany, NY (US); H. Jim FULFORD, Marianna, FL (US)

(73) Assignee: Tokyo Electron Limited, Tokyo (JP)

(21) Appl. No.: 19/057,614

(22) Filed: Feb. 19, 2025

(51) Int. Cl. H01L 21/687; H01L 21/66; H01L 21/67

(52) U.S. Cl. CPC H10P 72/7624; H10P 72/0616; H10P 74/203

(57) ABSTRACT

Aspects of the present disclosure provide a system for localized wafer pre-cooling for a hyperspectral imaging system. For example, the system can include a wafer chuck configured for holding a wafer thereon and moving and locating the wafer at a variety of heights. The system can further include a cooling fluid injection device configured for injecting a cooling fluid on a surface of the wafer held on the wafer chuck. The system can further include an optical column configured for directing a light beam through the cooling fluid onto the surface of the wafer. The system can further include an imaging device configured for capturing images of the wafer located at different heights and generating a three-dimension (3D) image based on the captured images.

### FIELD OF THE INVENTION

The present disclosure relates to semiconductor processing, and, in particular, to localized wafer pre-cooling for hyperspectral imaging system and method for three-dimension (3D) defect analysis in wafers.

### BACKGROUND

The background description provided herein is for the purpose of generally presenting the context of the disclosure. Work of the presently named inventors, to the extent the work is described in this background section, as well as aspects of the description that may not otherwise qualify as prior art at the time of filing, are neither expressly nor impliedly admitted as prior art against the present disclosure.

Semiconductor fabrication involves a variety of varied steps and processes. One typical fabrication process is known as photolithography (also called microlithography). Photolithography uses radiation, such as non-visible light (e.g., ultraviolet light) or visible light, to generate fine patterns in a semiconductor device design. Many types of semiconductor devices, such as diodes, transistors, and integrated circuits, can be constructed using semiconductor fabrication techniques including photolithography, etching, film deposition, surface cleaning, metallization, and so forth.

### SUMMARY

Aspects of the present disclosure provide a system for localized wafer pre-cooling for a hyperspectral imaging system. For example, the system can include a wafer chuck configured for holding a wafer thereon and moving and locating the wafer at a variety of heights. The system can further include a cooling fluid injection device configured for injecting a cooling fluid on a surface of the wafer held on the wafer chuck. The system can further include an optical column configured for directing a light beam through the cooling fluid onto the surface of the wafer. The system can further include an imaging device configured for capturing images of the wafer located at different heights and generating a three-dimension (3D) image based on the captured images. In an embodiment, the cooling fluid can be evaporated by energy of the light beam.

In an embodiment, the cooling fluid can be pre-cooled to a desired temperature before injected on the surface of the wafer. In some embodiments, the cooling fluid can be injected on a portion of the surface of the wafer. In various embodiments, the portion of the surface of the wafer can be under the optical column.

In an embodiment, the wafer chuck can use a split chuck magnetic design that includes an upper magnetic chuck having one or more upper magnets and a lower magnetic chuck having one or more lower magnets, and a magnetic field between the upper magnetic chuck and the lower magnetic chuck is enabled to interact with a magnetic force of attraction or repulsion such that the wafer is lowered or elevated. In some embodiments, the upper and lower magnets can be controlled individually such that magnetic fields generated between the upper and lower magnets are enabled to interact with magnetic forces of repulsion that increase from a first side of the wafer chuck to a second side of the wafer chuck opposite to the first side and the wafer held on the wafer chuck is tilted.

In an embodiment, the wafer can be held flat and the cooling fluid can be injected at an angle to the optical column.

In an embodiment, the imaging device can include a hyperspectral imaging device that is configured for generating the images of the wafer in multiple wavelengths to identify and classify defects in the wafer. For example, the wavelengths can include a non-visible spectrum.

Aspects of the present disclosure further provide a method for localized wafer pre-cooling. For example, the method can include holding a wafer at a first height, injecting a cooling fluid on a surface of the wafer, directing a light beam onto the surface of the wafer through the cooling fluid, capturing a first image of the wafer, moving the wafer to a second height, capturing a second image of the wafer, and generating a 3D image of the wafer based on the first image and the second image.

Note that this summary section does not specify every embodiment and/or incrementally novel aspect of the present disclosure or claimed invention. Instead, this summary only provides a preliminary discussion of different embodiments and corresponding points of novelty. For additional details and/or possible perspectives of the invention and embodiments, the reader is directed to the Detailed Description section and corresponding figures of the present disclosure as further discussed below.

### BRIEF DESCRIPTION OF THE DRAWINGS

Various embodiments of this disclosure that are proposed as examples will be described in detail with reference to the following figures, wherein like numerals reference like elements, and wherein:

FIGS. 1A and 1B are schematic diagrams of a first exemplary system localized wafer pre-cooling according to some embodiments of the present disclosure;

FIGS. 2A and 2B are schematic diagrams of a second exemplary system localized wafer pre-cooling according to some embodiments of the present disclosure;

FIGS. 3A and 3B are schematic diagrams of a third exemplary system localized wafer pre-cooling according to some embodiments of the present disclosure;

FIGS. 4A and 4B are schematic diagrams of a fourth exemplary system localized wafer pre-cooling according to some embodiments of the present disclosure;

FIGS. 5A and 5B are schematic diagrams of a fifth exemplary system localized wafer pre-cooling according to some embodiments of the present disclosure; and

FIG. 6 is a flow chart of an exemplary method for localized wafer pre-cooling according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “top,” “bottom,” “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

The present disclosure provides a system for localized pre-cooling of a wafer during laser exposure. In some embodiments, a cooling medium, e.g., a cooling fluid, can be pre-cooled to a desired temperature and then injected onto the surface of the wafer prior to each laser exposure, allowing for precise temperature control and preventing degradation of device properties. The system can include a hyperspectral imaging device, which enables 3D non-destructive testing for defect classification, providing higher resolution 3D inspection images. This novel and efficient approach facilitates advanced hyperspectral imaging and 3D defect analysis in wafers, thereby enhancing the defect analysis capabilities of tools such as the Trident tool. Depth of focus (DOF) can be reduced by the injection of the cooling fluid, and thus be smaller than feature sizes.

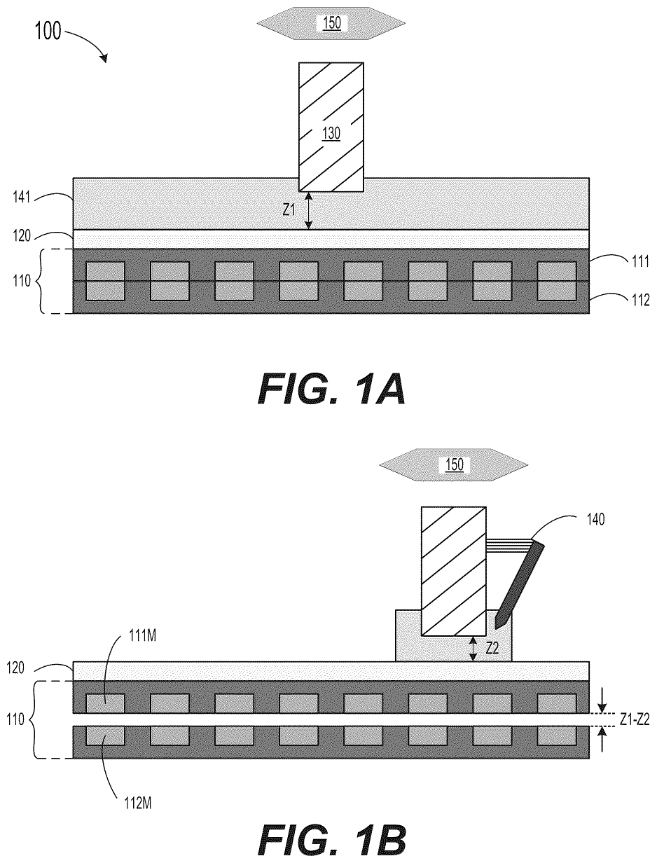

FIGS. 1A and 1B are schematic diagrams of an exemplary system 100 according to some embodiments of the present disclosure. In an embodiment, the system 100 can include a wafer chuck 110 that is configured for holding a wafer 120. In some embodiments, the wafer chuck 110 can elevate (i.e., move upward) and lower (i.e., move downward) the wafer 120 held thereon. In various embodiments, the wafer chuck 110 can use a split chuck magnetic design and include an upper magnetic chuck 111 and a lower magnetic chuck 112, each of which can include one or more magnets (e.g., upper magnets 111M and lower magnets 112M) and a magnetic field between which thus can be changed, e.g., enabled to interact with a magnetic force of attraction or repulsion, such that the wafer 120 can be elevated or lowered. For example, the magnetic field can be modulated to increase or decrease the magnetic regions in different states.

In an embodiment, the system 100 can further include an optical column (or an optical tower) 130 that is configured for directing a light beam (e.g., a laser beam) onto the wafer 120. In some embodiments, the optical column 130 can include a light source configured for generating a light beam (e.g., a laser beam) of various electromagnetic (EM) spectrum frequencies and one or more lenses configured for directing the light beam onto the surface of the wafer 120.

In an embodiment, the system 100 can further include a cooling fluid injection device 140 that is configured for injecting a cooling fluid 141 (e.g., water, air and coolant liquids) onto the surface of the wafer 120 to form an interface between the light beam generated by the optical column 130, which is immersed in the cooling fluid 141, and the surface of the wafer 120. In an embodiment, the cooling fluid 141 can be injected to cover the entire surface of the wafer 120, as shown in FIG. 1A. In another embodiment, the cooling fluid 141 can be injected to cover a (localized) portion of the surface of the wafer 120, e.g., under the optical column 130, as shown in FIG. 1B, and, accordingly, the wafer 120 can be cooled locally. In an embodiment, the cooling fluid injection device 140 can be located on either side of the optical column 130. In some embodiments, the cooling fluid 141 can be pre-cooled to a desired temperature. In various embodiments, the pre-cooled cooling fluid 141 can be evaporated by the energy of the light beam. In various embodiments, the wafer 120 is held flat, and the cooling fluid 141 is injected at an angle adjacent to the optical column 130 (or the light beam generated by the optical column 130).

In an embodiment, the system 100 can further include an imaging device 150 that is configured for capturing images of the wafer 120 that is located at different heights and generating a three-dimension (3D) image based on the captured images.

According to the present disclosure associated with the system 100, by using two different magnetic fields, which are generate by the upper and lower magnetic chucks 111 and 112, respectively, the wafer 120 can be moved and located at a variety of heights (or the wafer 120 can be apart from the optical column 130 at a variety of distances), e.g., Z1 or Z2, as shown in FIGS. 1A and 1B, respectively, and the imaging device 150 can record images of the wafer 120 in two different XYZ planes to generate a 3D detect image of the wafer 120. For example, the wafer chuck 110 may be moveable at ±1 nm increments X, Y, Z, allowing an image to be captured at each location and a holographic 3D defect image to be made accordingly. In an embodiment, the depth of focus (DOF) can be smaller than the size of the defect to obtain the 3D image. The present disclosure allows to look at 3D analysis of entire transistor or memory cell or any circuit element and to insert 3D defect into artificial intelligence (AI) engine.

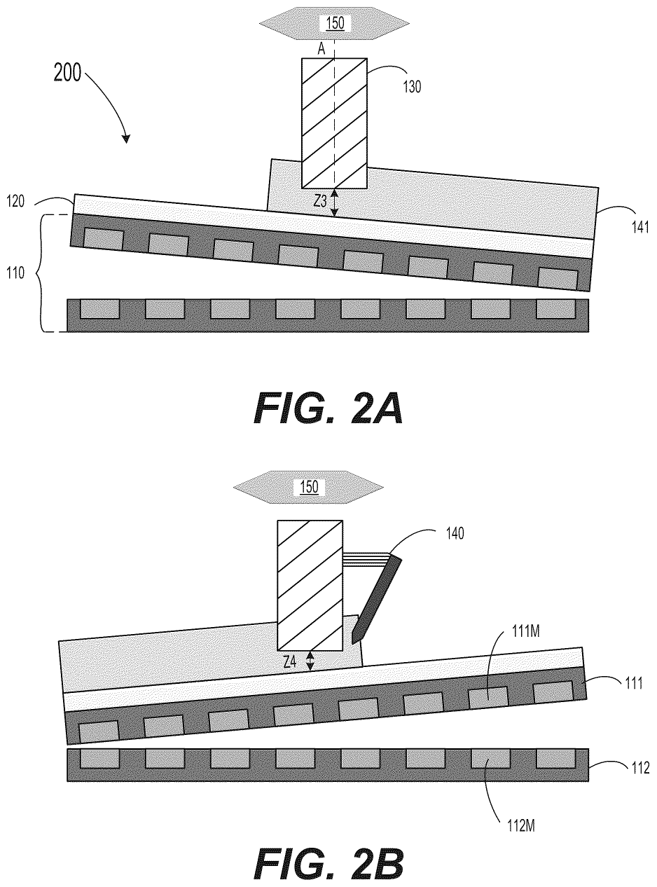

FIGS. 2A and 2B are schematic diagrams of an exemplary system 200 according to some embodiments of the present disclosure. The system 200 can also include the wafer chuck 110, the optical column 130, the cooling fluid injection device 140 and the imaging device 150. Different from the wafer 120 in the system 100 shown in FIGS. 1A and 1B, which is held flat, the wafer 120 in the system 200 can be tilted. Accordingly, the wafer 120 in the system 200 is at a slight angle to the optical column 130, allowing the cooling fluid 141 injected by the cooling fluid injection device 140 onto the surface of the wafer 120 to drain after the laser exposure is completed like a bubbling spring.

In an embodiment, the upper and lower magnets 111M and 112M can be individually controlled such that electric fields generated between the upper and lower magnets 111M and 112M can be enabled to interact with magnetic forces of repulsion that gradually increase from right side to the left side (as shown in FIG. 2A) or from the left side to the right side (as shown in FIG. 2B) of the wafer chuck 110. Accordingly, the wafer 120 can slope from right to left or from left to right, as shown in FIGS. 2A and 2B, respectively. In some embodiments, the wafer chuck 110 can also elevate or lower the wafer 120, by using two magnetic fields, to locate the wafer 120 at a variety of heights, e.g., Z3 or Z4, along a tilt and rotation axis A, as shown in FIGS. 2A and 2B, respectively.

In an embodiment, the cooling fluid 141 can be injected to cover the entire surface of the wafer 120. In another embodiment, the cooling fluid 141 can be injected to cover a (localized) portion of the surface of the wafer 120, e.g., under the optical column 130, as shown in FIGS. 2A and 2B, and, accordingly, the wafer 120 can be cooled locally. As the wafer 120 in the system 200 is tilted, once the cooling fluid 141, which is pre-cooled to a desired temperature, is injected in close proximity to a lens aperture of the optical column 130 and the laser exposure is completed, the cooling fluid 141 then will roll off the localized laser surface. According to the system 200, the cooling fluid 141 will form a slight waterfall as each laser exposure is completed.

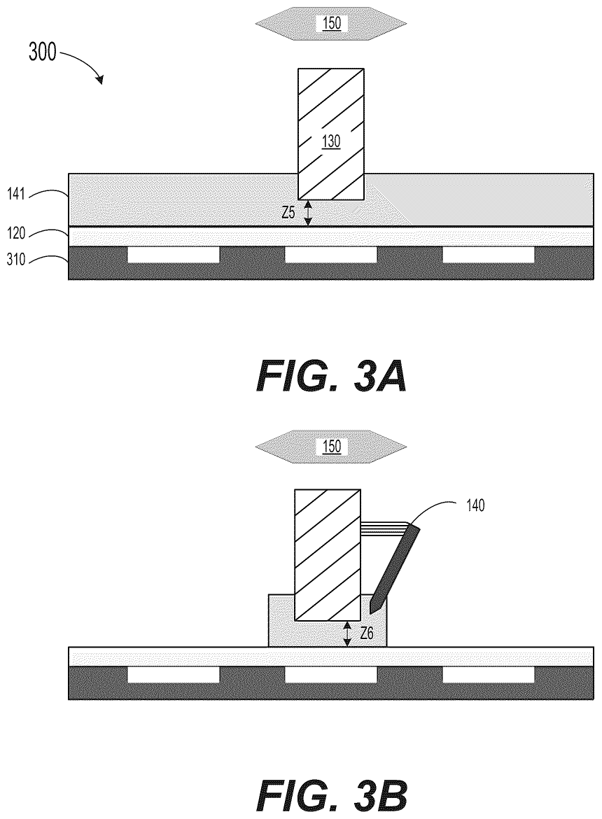

FIGS. 3A and 3B are schematic diagrams of an exemplary system 300 according to some embodiments of the present disclosure. The system 300 can also include the optical column 130, the cooling fluid injection device 140 and the imaging device 150. In an embodiment, the system 300 can further include a wafer chuck 310 that is also configured for holding the wafer 120. For example, the wafer chuck 310 can be a mechanical chuck, such as a vacuum chuck that uses a vacuum to attach the wafer 120 thereto. In some embodiments, the vacuum chuck 310 can be elevated or lowered such that the wafer 120 can be at a variety of heights, e.g., Z5 or Z6, as shown in FIGS. 3A and 3B, respectively. In an embodiment, the cooling fluid 141 can be injected to cover the entire surface of the wafer 120, as shown in FIG. 3A. In another embodiment, the cooling fluid 141 can be injected to cover a (localized) portion of the surface of the wafer 120, e.g., under the optical column 130, as shown in FIG. 3B, and, accordingly, the wafer 120 can be cooled locally.

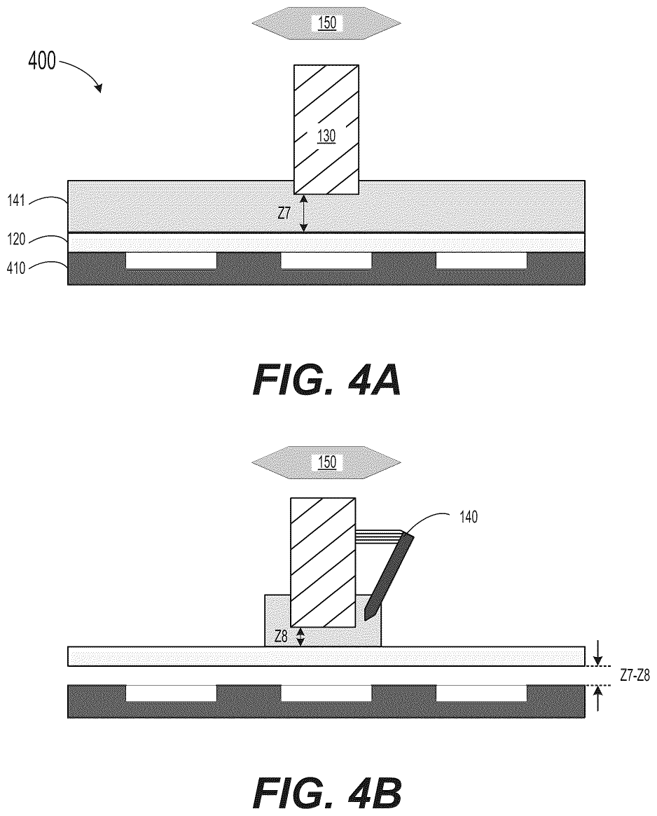

FIGS. 4A and 4B are schematic diagrams of an exemplary system 400 according to some embodiments of the present disclosure. The system 400 can also include the optical column 130 and the cooling fluid injection device 140. In an embodiment, the system 400 can further include a wafer chuck 410. For example, the wafer chuck 410 can also be a mechanical chuck, such as a vacuum chuck that uses a vacuum (attraction or repulsion) to either attach the wafer 120 thereto or repel the wafer 120 therefrom. Accordingly, the wafer 120 held thereon can then be elevated or lowered to a variety of heights, e.g., Z7 or Z8, as shown in FIGS. 4A and 4B, respectively.

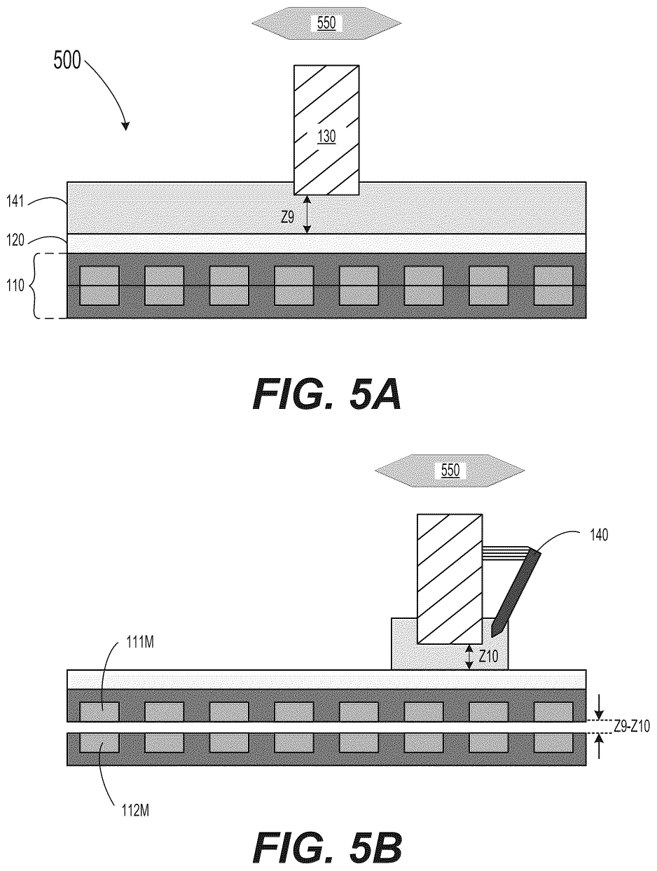

FIGS. 5A and 5B are schematic diagrams of an exemplary system 500 according to some embodiments of the present disclosure. The system 500 can also include a wafer chuck (e.g., the wafer chuck 110 or the wafer chuck 310), the optical column 130 and the cooling fluid injection device 140. In an embodiment, the system 500 can further include a hyperspectral imaging device (e.g., a hyperspectral camera) 550 that is configured for generating images of the wafer 120 in multiple wavelengths to identify and classify defects in the wafer 120, both in visible and non-visible spectrums. The hyperspectral imaging device 550 can collect and process, in a noninvasive and nondestructive way, detailed information about the composition and characteristics of objects and surfaces, e.g., the surface of the wafer 120, in order to identify and classify defects of the wafer 120.

In an embodiment, the localized pre-cooled cooling fluid 141 can allow for use of various different wavelengths since the energy of the laser beam is evaporated by the cooling fluid 141 injected and located on the surface of the wafer 120.

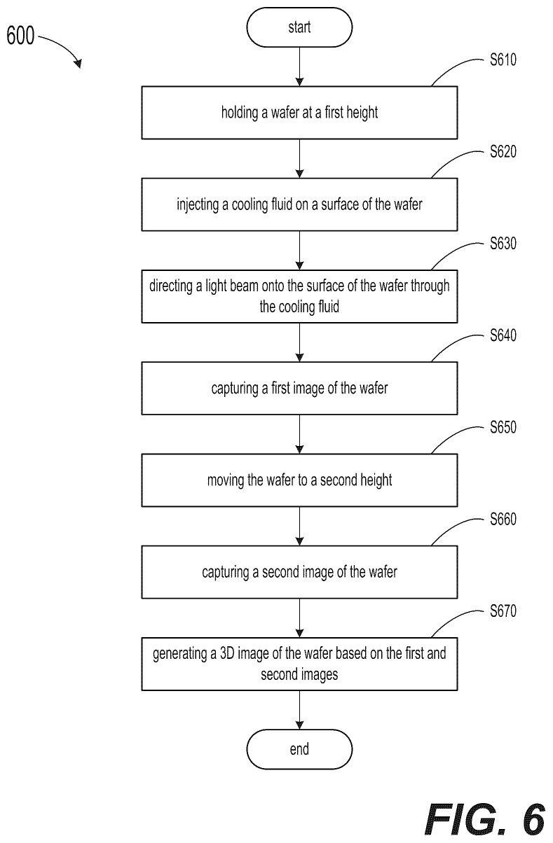

FIG. 6 is a flow chart of an exemplary method 600 according to some embodiments of the present disclosure. In various embodiments, some of the steps of the method 600 shown can be performed concurrently or in a different order than shown, can be substituted by other method steps, or can be omitted. Additional method steps can also be performed as desired. Aspects of the method 600 can be implemented by a localized wafer pre-cooling system, such as the systems 100-500 illustrated in and described with respect to the preceding figures. The method 600 can starts with step S610, at which a wafer is held at a first height. For example, the wafer chucks 110, 310 and 410 can be used to hold and locate the wafer 120 at the heights Z1, Z3, Z5, Z7 and Z7. The method 600 can proceed to step S620.

At step S620, a cooling fluid can be injected on a surface of the wafer. For example, the cooling fluid injection device 140 can be used to inject the cooling fluid 141 onto the surface of the wafer 120. The method 600 can proceed to step S630.

At step S630, a light beam can be directed onto the surface of the wafer through the cooling fluid. For example, the optical column 130 can be used to direct the light beam onto the surface of the wafer 120 through the cooling fluid 141. The method 600 can proceed to step S640.

At step S640, a first image of the wafer can be captured. For example, the imaging device 150 and the hyperspectral imaging device 550 can be used to capture the first image of the wafer 120, which is at the first height. The method 600 can proceed to step S650.

At step S650, the wafer can be moved to a second height. For example, the wafer chucks 110, 310 and 410 can be used to move the wafer 120 to the heights Z2, Z4, Z6, Z8 and Z10. The method 600 can proceed to step S660.

At step S660, a second image of the wafer can be captured. For example, the imaging device 150 and the hyperspectral imaging device 550 can be used to capture the second image of the wafer 120, which is at the second height. The method 600 can proceed to step S670.

At step S670, a 3D image of the wafer can be generated based on the first image and the second image. For example, the imaging device 150 and the hyperspectral imaging device 550 can be used to generate the 3D image based on the first and second images.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the present disclosure. The substrate may include any material portion or structure of a device, particularly a semiconductor or other electronics device, and may, for example, be a base substrate structure, such as a semiconductor wafer, reticle, or a dielectric layer on or overlying a base substrate structure such as a thin film. Thus, substrate is not limited to any particular base structure, underlying dielectric layer or overlying dielectric layer, patterned or un-patterned, but rather, is contemplated to include any such dielectric layer or base structure, and any combination of dielectric layers and/or base structures. The description may reference particular types of substrates, but this is for illustrative purposes only.

Those skilled in the art will also understand that there can be many variations made to the operations of the techniques explained above while still achieving the same objectives of the present disclosure. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A system, comprising:
a wafer chuck configured for holding a wafer thereon and moving and locating the wafer at a variety of heights;
a cooling fluid injection device configured for injecting a cooling fluid on a surface of the wafer held on the wafer chuck;
an optical column configured for directing a light beam through the cooling fluid onto the surface of the wafer; and
an imaging device configured for capturing images of the wafer located at different heights and generating a three-dimension (3D) image based on the captured images.

2. The system of claim 1, wherein the cooling fluid is pre-cooled to a desired temperature before injected on the surface of the wafer.

3. The system of claim 1, wherein the cooling fluid is injected on a portion of the surface of the wafer.

4. The system of claim 3, wherein the portion of the surface of the wafer is under the optical column.

5. The system of claim 1, wherein the cooling fluid is evaporated by energy of the light beam.

6. The system of claim 1, wherein the wafer chuck uses a split chuck magnetic design that includes an upper magnetic chuck having one or more upper magnets and a lower magnetic chuck having one or more lower magnets, and a magnetic field between the upper magnetic chuck and the lower magnetic chuck is enabled to interact with a magnetic force of attraction or repulsion such that the wafer is lowered or elevated.

7. The system of claim 6, wherein the upper and lower magnets are controlled individually such that magnetic fields generated between the upper and lower magnets are enabled to interact with magnetic forces of repulsion that increase from a first side of the wafer chuck to a second side of the wafer chuck opposite to the first side and the wafer held on the wafer chuck is tilted.

8. The system of claim 1, wherein the wafer is held flat and the cooling fluid is injected at an angle to the optical column.

9. The system of claim 1, wherein the imaging device includes a hyperspectral imaging device that is configured for generating the images of the wafer in multiple wavelengths to identify and classify defects in the wafer.

10. The system of claim 9, wherein the wavelengths include a non-visible spectrum.

11. A method, comprising:
holding a wafer at a first height;
injecting a cooling fluid on a surface of the wafer;
directing a light beam onto the surface of the wafer through the cooling fluid;
capturing a first image of the wafer;
moving the wafer to a second height;
capturing a second image of the wafer; and
generating a three-dimension (3D) image of the wafer based on the first image and the second image.

12. The method of claim 11, further comprising:
pre-cooling the cooling fluid to a desired temperature prior to injecting the cooling fluid on the surface of the wafer.

13. The method of claim 11, wherein the cooling fluid is injected on a portion of the surface of the wafer.

14. The method of claim 13, wherein the light beam is directed by an optical column and the portion of the surface of the wafer is under the optical column.

15. The method of claim 11, wherein the cooling fluid is evaporated by energy of the light beam.

16. The method of claim 11, wherein the wafer is tilted.

17. The method of claim 11, wherein the wafer is held flat and the cooling fluid is injected at an angle to the light beam.

18. The method of claim 11, wherein the first and second images are captured by a hyperspectral imaging device that is configured for generating images of the wafer in multiple wavelengths to identify and classify defects in the wafer.

19. The method of claim 18, wherein the wavelengths include a non-visible spectrum.

20. The method of claim 11, wherein the wafer is moved by a mechanical force or a magnetic force.
